(19) United States
(12) Patent Application Publication
(10) Pub. No.: US 2019/0304917 A1
(43) Pub. Date: Oct. 3, 2019

(54) HIGH DENSITY FAN-OUT WAFER LEVEL PACKAGE AND METHOD OF MAKING THE SAME

(71) Applicant: GLOBALFOUNDRIES Singapore Pte. Ltd., Singapore (SG)

(72) Inventor: Boo Yang JUNG, Singapore (SG)

(21) Appl. No.: 15/943,288

(22) Filed: Apr. 2, 2018

(51) Int. Cl. H01L 23/538; H01L 21/48; H01L 21/56; H01L 23/29; H01L 23/31; H01L 23/66; H01L 23/64; H01L 23/00

(52) U.S. Cl. CPC H01L 23/5389; H01L 2924/0715; H01L 21/4853; H01L 21/565; H01L 23/296; H01L 23/3114; H01L 23/5383; H01L 23/5386; H01L 23/66; H01L 23/645; H01L 24/19; H01L 24/20; H01L 2223/6677; H01L 2224/214; H01L 2924/1904; H01L 2924/19042; H01L 2924/19106; H01L 2924/15747; H01L 2924/186; H01L 21/4857

(57) ABSTRACT

Methods of producing a fan-out wafer level package and the resulting device are provided. Embodiments include forming vias in a first surface of a carrier wafer; filling the vias with a metal; forming a redistribution layer (RDL) over the carrier wafer, the RDL being in contact with the metal filled vias; attaching a semiconductor die to the RDL; forming a wafer mold over the semiconductor die; and removing a portion of the carrier wafer to expose the metal filled vias on a second surface of the carrier wafer.

### TECHNICAL FIELD

The present disclosure generally relates to semiconductor devices. In particular, the present disclosure relates to wafer level packaging.

### BACKGROUND

Fan-out wafer level packaging (FOWLP) is produced by the formation of a redistribution layer (RDL) with under bump metallization (UBM) on a support carrier including silicon or glass and a temporary sacrificial layer. Die-to-wafer bonding is performed followed by wafer molding. The process to produce the FOWLP further requires specialized debonding equipment and an extra debonding process. In particular, the debonding step is required at the interface between the support carrier and RDL prior to wafer bumping. This leads to higher costs and yield loss. Moreover, FOWLP for radio frequency (RF) applications requires additional space for an inductor or antenna which leads to higher costs due to a larger package size.

A need therefore exists for efficient methodology enabling formation of a high density FOWLP with reduced size and the resulting device.

### SUMMARY

An aspect of the present disclosure is using a carrier wafer during formation of a high density FOWLP. The carrier wafer remains in the final package structure and the RDL is formed on the carrier wafer. Another aspect of the present disclosure is including an antenna or inductor formed on the carrier wafer.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming vias in a first surface of a carrier wafer; filling the vias with a metal; forming a RDL over the carrier wafer, the RDL being in contact with the metal filled vias; attaching a semiconductor die to the RDL; forming a wafer mold over the semiconductor die; and removing a portion of the carrier wafer to expose the metal filled vias on a second surface of the carrier wafer.

Aspects of the present disclosure include filling the vias with contacts on the first surface of the carrier wafer. Other aspects include forming the vias in the carrier wafer with laser ablation. Another aspect includes removing the portion of the carrier wafer by way of grind. Further aspects include forming solder bumps or balls over the exposed metal filled vias on the second surface of the carrier wafer. Another aspect includes forming a plurality of RDLs over the carrier wafer.

Another aspect of the present disclosure is a method including: forming vias in a first surface of a carrier wafer; filling the vias with a metal; forming a first RDL over the carrier wafer, the first RDL being in contact with the metal filled vias; attaching a semiconductor die to the first RDL; forming a wafer mold over the semiconductor die; removing a portion of the carrier wafer to expose the metal filled vias on a second surface of the carrier wafer; and forming a dielectric passivation layer on second surface of the carrier wafer, the dielectric passivation layer including an antenna or inductor.

Aspects of the present disclosure include filling the vias with contacts on the first surface of the carrier wafer. Aspects of the present disclosure also include forming the vias in the carrier wafer with laser ablation. Other aspects include removing the portion of the carrier wafer by way of grinding. Another aspect includes forming solder bumps or balls over the dielectric passivation layer in contact with the metal filled vias on the second surface of the carrier wafer. Further aspects include the first RDL having a plurality of layers over the carrier wafer.

A further aspect of the present disclosure is a device including: metal vias formed in a carrier wafer extending from a first surface of the carrier wafer to a second surface of the carrier wafer; a RDL formed over the carrier wafer, the RDL being in contact with the metal filled vias; a semiconductor die formed over the RDL; a wafer mold formed over the semiconductor die; and solder bumps or balls formed on the second surface of the carrier wafer and in contact with the metal filled vias.

Aspects of the present disclosure include the metal filled vias being copper and including copper contacts formed on the first surface of the carrier wafer in contact with metal wiring of the RDL. Aspects of the present disclosure also include the RDL having a plurality of layers. Other aspects include the carrier wafer being a resin or polymer, and the wafer mold being an organic resin of fused silica. Another aspect includes the device being a fan-out wafer level package. Further aspects include a dielectric passivation layer formed between the solder bumps or balls and the carrier wafer. Another aspect includes the dielectric passivation layer having an antenna. Yet another aspect includes the dielectric passivation layer having an inductor.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1G schematically illustrate, in cross sectional views, a process flow for producing a FOWLP, in accordance with an exemplary embodiment; and

FIGS. 2A through 2G schematically illustrate, in cross sectional views, a process flow for producing a FOWLP for RF application, in accordance with another exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of needing specialized debonding equipment and extra processing steps to remove a support carrier and sacrificial layer during FOWLP production. The problem is solved, inter alia, by using a carrier wafer as the support carrier which remains in the final FOWLP, thereby eliminating the need for an extra and costly debonding step.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

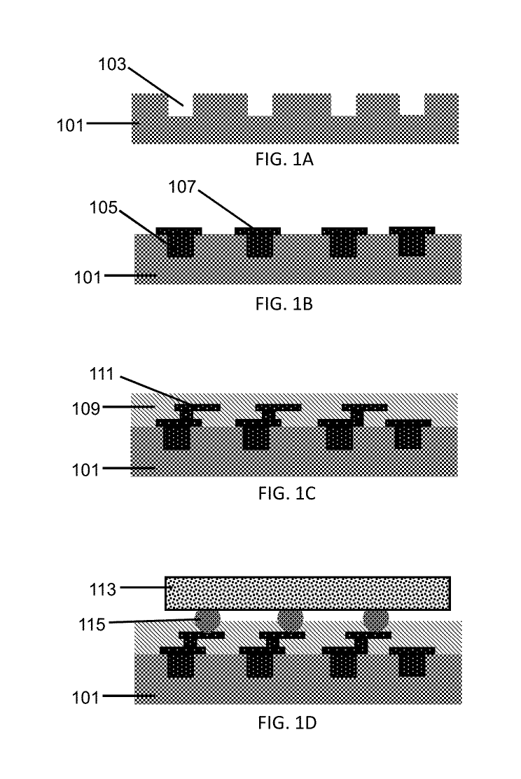

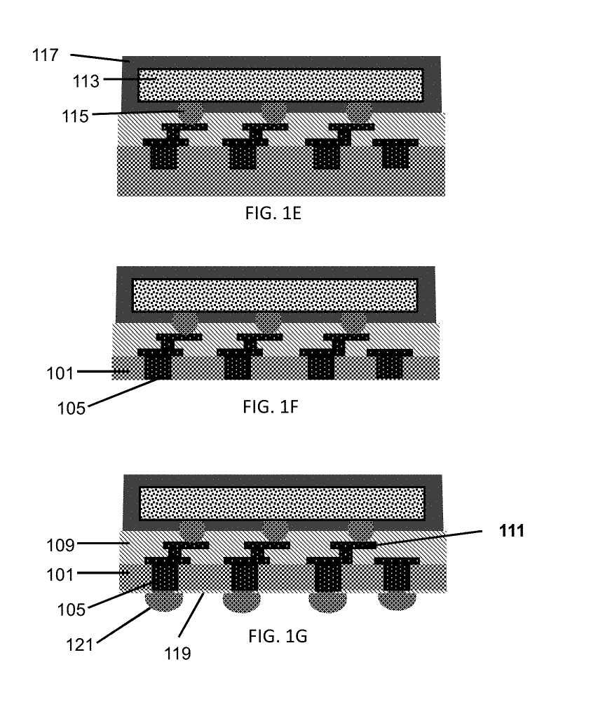

FIGS. 1A-1G illustrate a process flow for producing a FOWLP in accordance with an exemplary embodiment. In FIG. 1A, a carrier wafer 101 is provided and vias 103 are formed in the carrier wafer 101. The thickness of the carrier wafer can vary depending on device and package design and can be formed of a resin or polymer. A laser ablation process can be used to form the vias 103. An excimer laser operating at a 300 nanometer (nm) range can be used to form vias 103, such as laser blind vias. The depth of the vias 103 formed in the carrier wafer 101 can vary depending on device and package design.

In FIG. 1B, a the vias 103 are filled with a metal 105 and contact pads 107 are formed on the top surface of the carrier wafer 101. The metal can include copper (Cu), nickel (Ni), gold (Au), etc. The metal 105 is deposited by way of atomic layer deposition (ALD) or sputtering. In FIG. 1C, an RDL 109 is formed over the carrier wafer 101. The RDL 109 is a dielectric layer with metal contact pads 111 and makes the input/output (I/O) pads of a circuit available in other locations. The RDL 109 is formed of multiple layers and the thickness of the RDL 109 can vary depending on device and package design. The RDL 109 a polyimide with metal contact pads 111 distributed throughout.

Adverting to FIG. 1D, a chip on wafer process is performed to attach an active semiconductor die 113 to the contact pads 111 of the RDL 109 by way of solder bumps or balls 115. In FIG. 1E, a wafer molding step is performed to encapsulate or blanket the active semiconductor die 113 with a wafer mold 117. The wafer mold 117 can be formed of an organic resin of fused silica and the thickness can vary depending on device and package design.

In FIG. 1F, a grinding or polishing step is performed to remove a portion of the carrier wafer 101 to expose the metal vias 105 on a lower surface of the carrier wafer 101. The grinding or polishing step removes a portion of the carrier wafer 101.

In FIG. 1G, a polymer dielectric passivation layer 119 is formed and solder balls or bumps 121 are attached so that the solder bumps or balls 121 are connected to metal contact pad 111 through the pre-formed vias 105. The carrier wafer 101 is positioned between the RDL 109 and the solder bump or balls 121 in the final high density FOWLP.

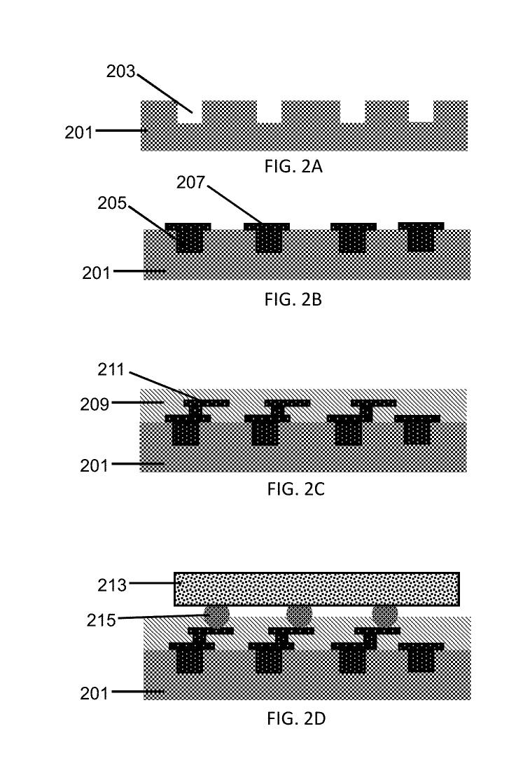

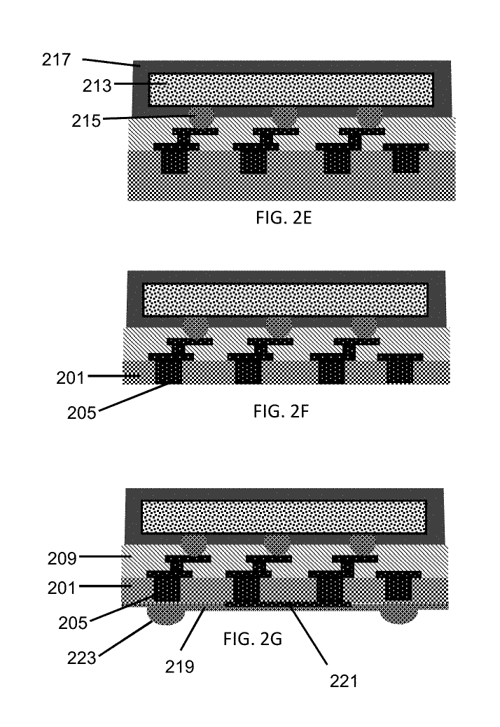

FIGS. 2A-2G illustrate a process flow for producing a FOWLP for RF application in accordance with an exemplary embodiment. In FIG. 2A, a carrier wafer 201 is provided and vias 203 are formed in the carrier wafer 201. The carrier wafer can be formed of a resin or polymer and its thickness can vary depending on device and package design. A laser ablation process can be used to form the vias 203. An excimer laser operating at a 300 nanometer (nm) range can be used to form vias 203, such as laser blind vias. The depth of vias 203 formed in the carrier wafer 201 can vary depending on device and package design.

In FIG. 2B, a the vias 203 are filled with a metal 205 and contact pads 207 are formed on the top surface of the carrier wafer 201. The metal can include copper (Cu), nickel (Ni), gold (Au), etc. The metal 205 is deposited by way of atomic layer deposition (ALD) or sputtering. In FIG. 2C, an RDL 209 is formed over the carrier wafer 201. The RDL 209 is a dielectric layer with metal contact pads 211 and makes the input/output (I/O) pads of a circuit available in other locations. The RDL 209 is formed of multiple layers with an overall thickness that can vary depending on device and package design. The RDL 209 a polyimide with metal contact pads 211 distributed throughout.

Adverting to FIG. 2D, a chip on wafer process is performed to attach an active semiconductor die 213 to the contact pads 211 of the RDL 209 by way of solder bumps or balls 215. In FIG. 2E, a wafer molding step is performed to encapsulate or blanket the active semiconductor die 213 with a wafer mold 217. The wafer mold 217 can be formed of an organic resin of fused silica. Its thickness can vary depending on device and package design.

In FIG. 2F, a grinding or polishing step is performed to remove a portion of the carrier wafer 201 to expose the metal vias 205 on a lower surface of the carrier wafer 201. The grinding or polishing step removes a portion of the carrier wafer 201.

In FIG. 2G, a polymer dielectric passivation layer 219 is formed. In this embodiment, an antenna or inductor 221 is formed in contact between vias 205. The antenna or inductor 221 is used for RF applications and has better performance in the carrier wafer 201 rather than a silicon area. Solder balls or bumps 223 are attached so that the solder bumps or balls 223 are connected to the RDL 209 through the pre-formed vias 205. The carrier wafer 201 is positioned between the RDL 209 and the solder bump or balls 221 in the final high density FOWLP.

The embodiments of the present disclosure can achieve several technical effects including reducing the size and cost during high density FOWLP. Embodiments of the present disclosure can also enjoy utility in various industrial applications as, for example, semiconductor fabrication plants that produce components used in microprocessors, smart phones, mobile phones, cellular handsets, set-top boxes, DVD recorders and players, automotive navigation, printers and peripherals, networking and telecom equipment, gaming systems, and digital cameras. The present disclosure enjoys industrial applicability in any of various types.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure can use various other combinations and embodiments and is capable of any changes or modifications within the scope of the inventive concept as expressed herein.

What is claimed is:

1. A method comprising:
forming vias in a first surface of a carrier wafer;
filling the vias with a metal;
forming a redistribution layer (RDL) over the carrier wafer, the RDL being in contact with the metal filled vias;
attaching a semiconductor die to the RDL;
forming a wafer mold over the semiconductor die; and
removing a portion of the carrier wafer to expose the metal filled vias on a second surface of the carrier wafer.

2. The method according to claim 1, further comprising:
filling the vias with contacts on the first surface of the carrier wafer.

3. The method according to claim 1, comprising:
forming the vias in the carrier wafer with laser ablation.

4. The method according to claim 1, comprising:
removing the portion of the carrier wafer by way of grinding.

5. The method according to claim 1, further comprising:
forming solder bumps or balls over the exposed metal filled vias on the second surface of the carrier wafer.

6. The method according to claim 1, comprising:
forming a plurality of RDLs over the carrier wafer.

7. A method comprising:
forming vias in a first surface of a carrier wafer;
filling the vias with a metal;
forming a first redistribution layer (RDL) over the carrier wafer, the first RDL being in contact with the metal filled vias;
attaching a semiconductor die to the first RDL;
forming a wafer mold over the semiconductor die;
removing a portion of the carrier wafer to expose the metal filled vias on a second surface of the carrier wafer; and
forming a dielectric passivation layer on second surface of the carrier wafer, the dielectric passivation layer comprising an antenna or inductor.

8. The method according to claim 1, further comprising:
filling the vias with contacts on the first surface of the carrier wafer.

9. The method according to claim 7, comprising:
forming the vias in the carrier wafer with laser ablation.

10. The method according to claim 7, comprising:
removing the portion of the carrier wafer by way of grinding.

11. The method according to claim 7, further comprising:
forming solder bumps or balls over the dielectric passivation layer in contact with the metal filled vias on the second surface of the carrier wafer.

12. The method according to claim 7, wherein the first RDL comprises a plurality of layers over the carrier wafer.

13. A device comprising:
metal vias formed in a carrier wafer extending from a first surface of the carrier wafer to a second surface of the carrier wafer;
a redistribution layer (RDL) formed over the carrier wafer, the RDL being in contact with the metal filled vias;
a semiconductor die formed over the RDL;
a wafer mold formed over the semiconductor die; and
solder bumps or balls formed on the second surface of the carrier wafer and in contact with the metal filled vias.

14. The device according to claim 13, wherein the metal filled vias comprise copper and include copper contacts formed on the first surface of the carrier wafer in contact with metal wiring of the RDL.

15. The device according to claim 14, wherein the RDL comprises a plurality of layers.

16. The device according to claim 13,
wherein the carrier wafer comprises a resin or polymer, and
wherein the wafer mold comprises an organic resin of fused silica.

17. The device according to claim 13, wherein the device comprises a fan out wafer level package.

18. The device according to claim 13, further comprising:
a dielectric passivation layer formed between the solder bumps or balls and the carrier wafer.

19. The device according to claim 18, wherein the dielectric passivation layer comprises an antenna.

20. The device according to claim 18, wherein the dielectric passivation layer comprises an inductor.
